(19) United States
(12) Patent Application Publication
(10) Pub. No.: US 2025/0089279 A1
(43) Pub. Date: Mar. 13, 2025

(54) HIGH-VOLTAGE CAPACITOR AND METHOD FOR MANUFACTURING SAME, AND INTEGRATED DEVICE

(71) Applicant: Silergy Semiconductor Technology (Hangzhou) LTD., Hangzhou (CN)

(72) Inventors: Zheng LV, Hangzhou (CN); Chuan PENG, Hangzhou (CN); Xunyi SONG, Hangzhou (CN)

(73) Assignee: Silergy Semiconductor Technology (Hangzhou) LTD., Hangzhou (CN)

(21) Appl. No.: 18/830,619

(22) Filed: Sep. 11, 2024

(30) Foreign Application Priority Data
Sep. 11, 2023 (CN) 2023111740441
Dec. 1, 2023 (CN) 202311642460X

(51) Int. Cl. H01G 4/30

(52) U.S. Cl. CPC H10D 1/692

(57) ABSTRACT

A high-voltage capacitor and a method for manufacturing the high-voltage capacitor are provided. The high-voltage capacitor comprises a first electrode portion, interlayer dielectric layers, a first voltage-resistant dielectric layer, a second electrode portion, and a second voltage-resistant dielectric layer. The interlayer dielectric layers are stacked on the first electrode portion. The first voltage-resistant dielectric layer is formed on an upper surface of a topmost interlayer dielectric layer among the interlayer dielectric layers. The second electrode portion is formed on the first voltage-resistant dielectric layer, and projections of the second electrode portion and the first electrode portion overlap along a vertical direction. The second voltage-resistant dielectric layer covers a side surface and part of an upper surface of the second electrode portion. A dielectric constant of each of the first voltage-resistant dielectric layer and the second voltage-resistant dielectric layer is greater than a dielectric constant of the interlayer dielectric layers.

### CROSS REFERENCE TO RELATED APPLICATION

The present disclosure claims the benefit of priority to Chinese Patent Applications No. CN 202311174044.1, entitled “HIGH-VOLTAGE CAPACITOR AND METHOD FOR MANUFACTURING SAME, AND INTEGRATED DEVICE”, filed with CNIPA on Sep. 11, 2023, and No. 202311642460.X, entitled “HIGH-VOLTAGE CAPACITOR AND METHOD FOR MANUFACTURING SAME, AND INTEGRATED DEVICE”, filed with CNIPA on Dec. 1, 2023, the disclosure of which is incorporated herein by reference in its entirety for all purposes.

### FIELD OF THE INVENTION

The present disclosure relates to the technical field of semiconductors, and in particular, to a high-voltage capacitor, a method for manufacturing the high-voltage capacitor, and an integrated device.

### BACKGROUND OF THE INVENTION

High-voltage capacitors can be integrated into functional semiconductor chips or packaged together with them to act as capacitive isolators, which are used for isolating different voltage domains, including in automotive isolation devices, which ensure the safe transmission of electrical signals between different voltage domains. However, current technology fails to offer the required isolation voltage and voltage withstand uniformity for these applications. There's a need to enhance these aspects in high-voltage capacitors. The challenge is that improving isolation voltage and voltage withstand uniformity significantly increases costs and process complexity. Therefore, the urgent issue is how to improve these characteristics without substantially increasing costs and process complexity.

### SUMMARY OF THE INVENTION

The present disclosure provides a high-voltage capacitor, a method for manufacturing the high-voltage capacitor, and an integrated device, all of which enhance both the isolation voltage and voltage withstand uniformity of the high-voltage capacitor.

A first aspect of the present disclosure provides a method for manufacturing a high-voltage capacitor. The method for manufacturing the high-voltage capacitor comprises forming a first electrode portion of the high-voltage capacitor; stacking one or more interlayer dielectric layers on the first electrode portion; forming a first voltage-resistant dielectric layer on an upper surface of a topmost interlayer dielectric layer among the interlayer dielectric layers; forming a second electrode portion of the high-voltage capacitor on the first voltage-resistant dielectric layer, wherein projections of the second electrode portion and the first electrode portion overlap along a vertical direction; and forming a second voltage-resistant dielectric layer on the second electrode portion and exposed portion of an upper surface of first voltage-resistant dielectric layer, wherein a dielectric constant of each of the first voltage-resistant dielectric layer and the second voltage-resistant dielectric layer is greater than a dielectric constant of the interlayer dielectric layers.

Further, the forming of the first voltage-resistant dielectric layer comprises forming one layer of voltage-resistant dielectric structure covering the upper surface of the topmost interlayer dielectric layer, and materials of the first voltage-resistant dielectric layer and the second voltage-resistant dielectric layer are the same.

Further, the forming of the first voltage-resistant dielectric layer comprises forming a lower voltage-resistant dielectric layer covering the upper surface of the topmost interlayer dielectric layer; forming an upper voltage-resistant dielectric layer on the lower voltage-resistant dielectric layer; and etching the upper voltage-resistant dielectric layer after the second electrode portion is formed on the upper voltage-resistant dielectric layer, to obtain an etched upper voltage-resistant dielectric layer located only below a lower surface of the second electrode portion.

Further, the second voltage-resistant dielectric layer is located on the lower voltage-resistant dielectric layer and the second electrode portion, and covers an exposed portion of an upper surface of the lower voltage-resistant dielectric layer, the side surface and the upper surface of the second electrode portion, and a side surface of the upper voltage-resistant dielectric layer.

Further, before forming the second voltage-resistant dielectric layer covering the side surface and the upper surface of the second electrode portion, the method further comprises: forming a fourth voltage-resistant dielectric layer on the first voltage-resistant dielectric layer to cover the side surface of the second electrode portion.

Further, the second voltage-resistant dielectric layer is located on the lower voltage-resistant dielectric layer and the second electrode portion to cover an exposed portion of an upper surface of the lower voltage-resistant dielectric layer, the upper surface of the second electrode portion, and a side surface of the fourth voltage-resistant dielectric layer.

Further, the upper voltage-resistant dielectric layer is made of one of SiON and SiN, and the lower voltage-resistant dielectric layer is made of the other of SiON and SiN.

Further, a third voltage-resistant dielectric layer is formed between every two adjacent interlayer dielectric layers.

A second aspect of the present disclosure provides a high-voltage capacitor, comprising a first electrode portion, one or more interlayer dielectric layers, a first voltage-resistant dielectric layer, a second electrode portion, and a second voltage-resistant dielectric layer. The interlayer dielectric layers are stacked on the first electrode portion. The first voltage-resistant dielectric layer is formed on an upper surface of a topmost interlayer dielectric layer among the interlayer dielectric layers. The second electrode portion is formed on the first voltage-resistant dielectric layer, and projections of the second electrode portion and the first electrode portion overlap along a vertical direction. The second voltage-resistant dielectric layer is formed on the second electrode portion and exposed portion of an upper surface of first voltage-resistant dielectric layer to at least cover part of an upper surface of the second electrode portion. A dielectric constant of each of the first voltage-resistant dielectric layer and the second voltage-resistant dielectric layer is greater than a dielectric constant of the interlayer dielectric layers.

Further, materials of the first voltage-resistant dielectric layer and the second voltage-resistant dielectric layer are the same.

Further, the first voltage-resistant dielectric layer comprises a lower voltage-resistant dielectric layer and an upper voltage-resistant dielectric layer, and materials of the second voltage-resistant dielectric layer and the lower voltage-resistant dielectric layer are the same. The lower voltage-resistant dielectric layer is away from a lower surface of the second electrode portion compared to the upper voltage-resistant dielectric layer.

Further, the high-voltage capacitor further comprises a fourth voltage-resistant dielectric layer. The fourth voltage-resistant dielectric layer is formed on the first voltage-resistant dielectric layer and is configured to cover the side surface of the second electrode portion.

Further, the second voltage-resistant dielectric layer is located on the lower voltage-resistant dielectric layer and the second electrode portion, and covers an exposed portion of an upper surface of the lower voltage-resistant dielectric layer, the upper surface of the second electrode portion, and a side surface of the fourth voltage-resistant dielectric layer. Materials of the fourth voltage-resistant dielectric layer and the upper voltage-resistant dielectric layer are the same.

Further, the first voltage-resistant dielectric layer and the second voltage-resistant dielectric layer are made of SiON or SiN.

Further, the lower voltage-resistant dielectric layer is made of one of SiON and SiN, and the upper voltage-resistant dielectric layer is made of the other of SiON and SiN.

Further, the lower voltage-resistant dielectric layer covers the entire upper surface of the topmost interlayer dielectric layer, and the upper voltage-resistant dielectric layer is located only below the lower surface of the second electrode portion.

Further, the interlayer dielectric layers and the first voltage-resistant dielectric layer are located between the first electrode portion and the second electrode portion, and have a total thickness greater than or equal to 5 μm and less than or equal to 25 μm.

Further, a thickness of the first voltage-resistant dielectric layer is greater than or equal to 0.5 μm and less than or equal to 3 μm.

Further, a third voltage-resistant dielectric layer is located between every two adjacent interlayer dielectric layers.

A third aspect of the present disclosure provides an integrated device, comprising a substrate, the above-mentioned high-voltage capacitor, metal layers, and conductive via holes. The substrate comprises a first region and a second region, and the second region is provided with a semiconductor device. The high-voltage capacitor is located above the first region. The metal layers and conductive via holes are located in the interlayer dielectric layers and above the second region. The metal layers and the conductive via holes are configured to lead out electrodes of the semiconductor device, the first electrode portion is formed synchronously with a metal layer located in a same interlayer dielectric layer as the first electrode portion, and the second electrode portion is formed synchronously with a metal layer located in a same interlayer dielectric layer as the second electrode portion.

By placing the first voltage-resistant dielectric layer beneath the second electrode portion, and configuring the dielectric constant of each of the first voltage-resistant dielectric layer and the second voltage-resistant dielectric layer to be greater than the dielectric constant of the interlayer dielectric layers, the high-voltage capacitor of the present disclosure enhances its voltage resistance. Additionally, the first voltage-resistant dielectric layer is composed of two layers, further increasing the dielectric layer's thickness and enhancing the capacitor's voltage resistance. Moreover, the second voltage-resistant dielectric layer is located on both the upper and side surfaces of the second electrode portion to cover its corners, reducing electric field concentration. The second voltage-resistant dielectric layer is made of the same material as the first voltage-resistant dielectric layer or the lower voltage-resistant dielectric layer to prevent delamination, thereby improving the device's performance.

### BRIEF DESCRIPTION OF DRAWINGS

The above and other objects, features and advantages of the present disclosure will become more apparent from the following description of embodiments of the disclosure with reference to the accompanying drawings, in which:

FIG. 1 is a cross-sectional view of a high-voltage capacitor according to a first embodiment of the present disclosure;

FIG. 2 is a cross-sectional view of a high-voltage capacitor according to a second embodiment of the present disclosure;

FIG. 3 is a cross-sectional view of a high-voltage capacitor according to a third embodiment of the present disclosure;

FIG. 4 is a cross-sectional view of a high-voltage capacitor according to a fourth embodiment of the present disclosure;

FIG. 5 is a cross-sectional view of a high-voltage capacitor according to a fifth embodiment of the present disclosure;

FIGS. 6A-6D are cross-sectional views showing intermediate structures obtained after various steps of a method for manufacturing a high-voltage capacitor according to an embodiment of the present disclosure;

FIGS. 7A-7D are cross-sectional views showing intermediate structures obtained after various steps of a method for manufacturing a high-voltage capacitor according to another embodiment of the present disclosure.

### DETAILED DESCRIPTION OF THE INVENTION

The following description of the present disclosure is based on exemplary embodiments; however, the present disclosure is not restricted to these embodiments. In the detailed description below, specific details are provided to facilitate a thorough understanding of the present disclosure. It will be apparent to those skilled in the art that the present disclosure can be practiced without these specific details. To avoid obscuring the essence of the present disclosure, well-known methods, processes, procedures, components, and circuits are not described in detail.

Moreover, it should be understood by those skilled in the art that the accompanying drawings are provided for illustrative purposes and are not necessarily drawn to scale.

In the present disclosure, unless otherwise expressly specified, terms such as “install”, “connect”, “couple”, and “fix” should be broadly understood. For example, when one element is referred to as being “connected to” another element, one element may be fixedly connected to or detachably connected to another element, may be integrally connected to another element, may be mechanically connected to or electrically connected to another element, may be directly connected to another element, or may be indirectly connected to another element with another element interposed therebetween. These two elements may also communicate with each other internally or interact with each other. Those of ordinary skill in the art can understand the specific meanings of the above terms in the present disclosure according to specific situations.

Spatial terms, such as “inner”, “outer”, “below”, “beneath”, “lower”, “above”, “upper”, etc., can be used herein to facilitate the description of the relationship between one element or feature and another element or feature shown in the figures. It will be understood that these spatial relationship terms are intended to encompass different orientations of the device in use or operation other than those depicted in the drawings. For example, if the device depicted in the drawings is turned over, elements described as being “below” or “beneath” other elements or features would then be oriented as “above” the other elements or features. Thus, the exemplary term “below” can encompass both orientations. The device may be otherwise oriented (rotated 90 degrees or at other orientations), and the spatially relative descriptors used herein should be interpreted accordingly.

The terms “comprising”, “including”, and similar terms throughout the present disclosure should be interpreted as inclusive rather than exclusive or exhaustive; that is, meaning “including, but not limited to.”

It should be understood that the terms “first” and “second” are used for indication purpose only and should not be construed as indicating or implying relative importance. Furthermore, in the present disclosure, “a plurality of” means two or more, unless otherwise expressly specified.

It should be noted that the following embodiments and the features of the following embodiments can be combined with each other if no conflict will result.

The technical solutions of the present disclosure will be further described below in conjunction with the accompanying drawings and specific embodiments.

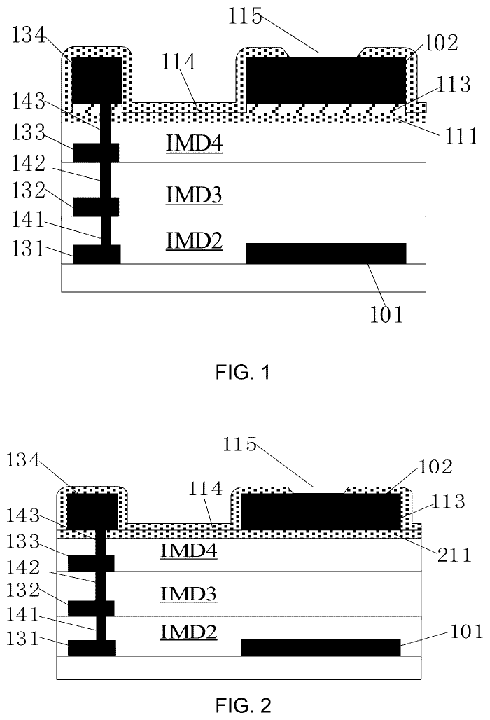

FIG. 1 is a cross-sectional view of a high-voltage capacitor according to a first embodiment of the present disclosure. The high-voltage capacitor includes a first electrode portion 101, one or more interlayer dielectric layers, a first voltage-resistant dielectric layer, a second electrode portion 102, and a second voltage-resistant dielectric layer 114. The interlayer dielectric layers are stacked on the first electrode portion 101. The first voltage-resistant dielectric layer is formed on an upper surface of a topmost interlayer dielectric layer among the interlayer dielectric layers. It should be noted that when the high-voltage capacitor has only one interlayer dielectric layer, the topmost interlayer dielectric layer is the single interlayer dielectric layer. The second electrode portion 102 is formed on the first voltage-resistant dielectric layer. The second voltage-resistant dielectric layer 114 covers a side surface and part of an upper surface of the second electrode portion 102. A dielectric constant of each of the first voltage-resistant dielectric layer and the second voltage-resistant dielectric layer 114 is greater than a dielectric constant of the interlayer dielectric layers. The first electrode portion 101 and the second electrode portion 102 are aligned along a first direction, and the first direction is a stacking direction of the high-voltage capacitor. Additionally, the first direction is set as the vertical direction. In other words, projections of the second electrode portion and the first electrode portion overlap along the vertical direction. As an example, the first electrode portion 101 is configured as a lower electrode plate of the high-voltage capacitor, and the second electrode portion 102 is configured as an upper electrode plate of the high-voltage capacitor. The second voltage-resistant dielectric layer 114 on the upper surface of the second electrode portion 102 is etched to form an opening 115, exposing part of the upper surface of the second electrode portion 102, such that the second electrode portion 102 can be electrically connected to an external circuit.

As an example, the first voltage-resistant dielectric layer includes a lower voltage-resistant dielectric layer 111 and an upper voltage-resistant dielectric layer 113. The lower voltage-resistant dielectric layer 111 covers the entire upper surface of the topmost interlayer dielectric layer, and the upper voltage-resistant dielectric layer 113 is located only below a lower surface of the second electrode portion 102. The second voltage-resistant dielectric layer 114 is located on the second electrode portion 102 and an exposed portion of an upper surface of the lower voltage-resistant dielectric layer 111, and covers the side surfaces of both the second electrode portion 102 and the upper voltage-resistant dielectric layer 113. The upper voltage-resistant dielectric layer 113 and the lower voltage-resistant dielectric layer 111 are made of different materials, the upper voltage-resistant dielectric layer 113 is made of one of SiON and SiN, and the lower voltage-resistant dielectric layer 111 is made of the other of SiON and SiN. The material of the second voltage-resistant dielectric layer 114 is the same as the material of one of the upper voltage-resistant dielectric layer 113 and the lower voltage-resistant dielectric layer 111. Preferably, the material of the second voltage-resistant dielectric layer 114 is the same as that of the lower voltage-resistant dielectric layer 111, such that the second electrode portion 102 can be better surrounded, and the voltage resistance of the high-voltage capacitor is prevented from being affected by delamination. Further, a thickness of the second voltage-resistant dielectric layer varies between 1 μm and 4 μm, and a thickness of the first voltage-resistant dielectric layer is greater than or equal to 0.5 μm and less than or equal to 3 μm.

In other embodiments, the first voltage-resistant dielectric layer can include only a one-layer dielectric structure 211, as shown in FIG. 2, the one-layer dielectric structure 211 covers the upper surface of the topmost interlayer dielectric layer, and the one-layer dielectric structure 211 can be made of SiN or SiON. Preferably, the second voltage-resistant dielectric layer 114 is made of the same material as the one-layer dielectric structure 211, to better surround the second electrode portion.

As an example, the high-voltage capacitor includes three interlayer dielectric layers, including a second interlayer dielectric layer IMD2, a third interlayer dielectric layer IMD3, and a fourth interlayer dielectric layer IMD4. The second interlayer dielectric layer IMD2, the third interlayer dielectric layer IMD3, and the fourth interlayer dielectric layer IMD4 are disposed between the first electrode portion 101 and the second electrode portion 102, and the second interlayer dielectric layer IMD2 further covers a side surface of the first electrode portion 101. The first electrode portion 101 is disposed on a first interlayer dielectric layer. The interlayer dielectric layers and the first voltage-resistant dielectric layer are located between the first electrode portion 101 and the second electrode portion 102, and have a total thickness greater than or equal to 5 μm and less than or equal to 25 μm. In other embodiments, other interlayer dielectric layers can be included between the first electrode portion 101 and the second electrode portion 102, and each of the other interlayer dielectric layers can be placed between any adjacent layers. The number of the interlayer dielectric layers can be adjusted based on the required voltage resistance of the high-voltage capacitor; as shown in FIG. 5, the high-voltage capacitor comprises five interlayer dielectric layers, specifically, the second interlayer dielectric layer IMD2, the third interlayer dielectric layer IMD3, the fourth interlayer dielectric layer IMD4, and a fifth interlayer dielectric layer IMD5.

It's important to note that the high-voltage capacitor is typically integrated into a semiconductor die. This die comprises a semiconductor substrate that having active devices, such as metal-oxide-semiconductor transistors. The semiconductor substrate has both a high-voltage capacitor region and an active region. The metal layers (131, 132, 133, 134) and conductive via holes (141, 142, 143) are formed above the active region, and all of the metal layers and the conductive via holes are configured to lead out electrodes of the active devices. The conductive via holes are electrically connected to adjacent metal layers. Each of the interlayer dielectric layers includes one metal layer and at least one conductive via hole. As an example, the metal layer 131 is on the same layer as the first electrode portion 101, and the metal layer 134 is on the same layer as the second electrode portion 102. Additionally, part of the first voltage-resistant dielectric layer is located beneath a lower surface of the metal layer 134. The conductive via hole 143 starts from the metal layer 133 and sequentially passes through the interlayer dielectric layer IMD4, the lower voltage-resistant dielectric layer 111, and the upper voltage-resistant dielectric layer 113, and finally reaches the metal layer 134.

The present disclosure further provides an integrated device, comprising a substrate, the above-mentioned high-voltage capacitor, metal layers, and conductive via holes. The substrate comprises a first region and a second region, and the second region is provided with a semiconductor device. The high-voltage capacitor is located above the first region. The metal layers and conductive via holes are located in the interlayer dielectric layers and above the second region. The metal layers and the conductive via holes are configured to lead out electrodes of the semiconductor device, the first electrode portion is formed synchronously with a metal layer located in a same interlayer dielectric layer as the first electrode portion, and the second electrode portion is formed synchronously with a metal layer located in a same interlayer dielectric layer as the second electrode portion.

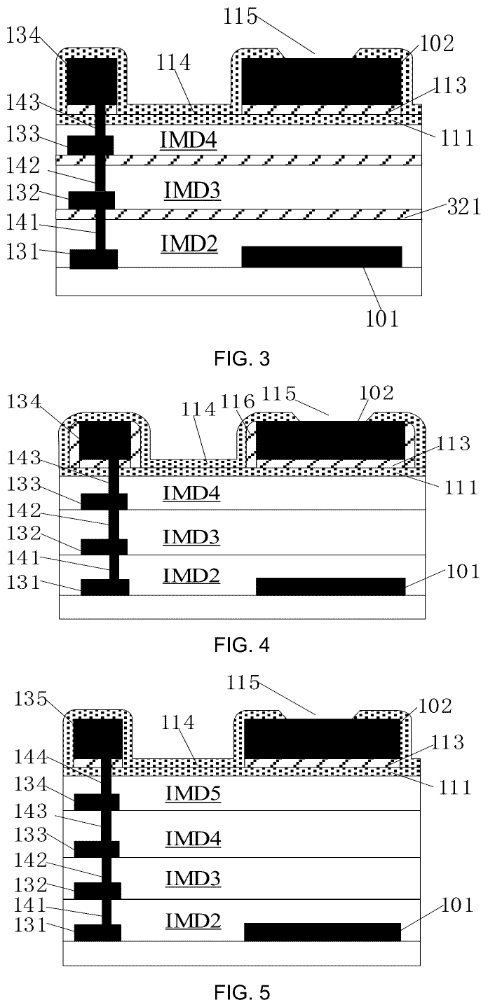

FIG. 3 is a cross-sectional view of a high-voltage capacitor according to a third embodiment of the present disclosure. The main difference between the third embodiment and the first embodiment in FIG. 1 is that in third embodiment, a third voltage-resistant dielectric layer is located between every two adjacent interlayer dielectric layers.

Specifically, between the first electrode portion 101 and the second electrode portion 102, a third voltage-resistant dielectric layer 321 is provided between every two adjacent interlayer dielectric layers of the high-voltage capacitor. The third voltage-resistant dielectric layers 321 can be made of SiN or SiON. Further, in the active region of the semiconductor die, a third voltage-resistant dielectric layer 321 is located below each metal layer and is in contact with each metal layer.

By placing a third voltage-resistant dielectric layer between every two adjacent interlayer dielectric layers, the voltage resistance of the high-voltage capacitor is further enhanced.

FIG. 4 is a cross-sectional view of a high-voltage capacitor according to a fourth embodiment of the present disclosure. The only difference between the fourth embodiment and the first embodiment in FIG. 1 is that in the fourth embodiment, a fourth voltage-resistant dielectric layer 116 is formed on the first voltage-resistant dielectric layer, to cover the side surface of the second electrode portion. Specifically, the fourth voltage-resistant dielectric layer 116 is located on the lower voltage-resistant dielectric layer 111, and covers the side surfaces of the upper voltage-resistant dielectric layer 113 and the second electrode portion 102. In other embodiment, the fourth voltage-resistant dielectric layer 116 can be located on the upper voltage-resistant dielectric layer 113, and covers the side surfaces of the upper voltage-resistant dielectric layer 113.

The second voltage-resistant dielectric layer 114 is located on the lower voltage-resistant dielectric layer and the second electrode portion 102, and covers the exposed portion of the upper surface of the lower voltage-resistant dielectric layer, the upper surface of the second electrode portion 102, and a side surface of the fourth voltage-resistant dielectric layer 116. Materials of the fourth voltage-resistant dielectric layer 116 and the upper voltage-resistant dielectric layer are the same, that is, the fourth voltage-resistant dielectric layer 116 can be made of SiN or SiON.

The present disclosure further provides a method for manufacturing a high-voltage capacitor, comprising: forming a first electrode portion of the high-voltage capacitor; stacking one or more interlayer dielectric layers on the first electrode portion; forming a first voltage-resistant dielectric layer on an upper surface of a topmost interlayer dielectric layer among the interlayer dielectric layers; forming a second electrode portion of the high-voltage capacitor on the first voltage-resistant dielectric layer, where the second electrode portion and the first electrode portion are aligned along a vertical direction; and forming a second voltage-resistant dielectric layer covering a side surface and an upper surface of the second electrode portion, where a dielectric constant of each of the first voltage-resistant dielectric layer and the second voltage-resistant dielectric layer is greater than a dielectric constant of the interlayer dielectric layers.

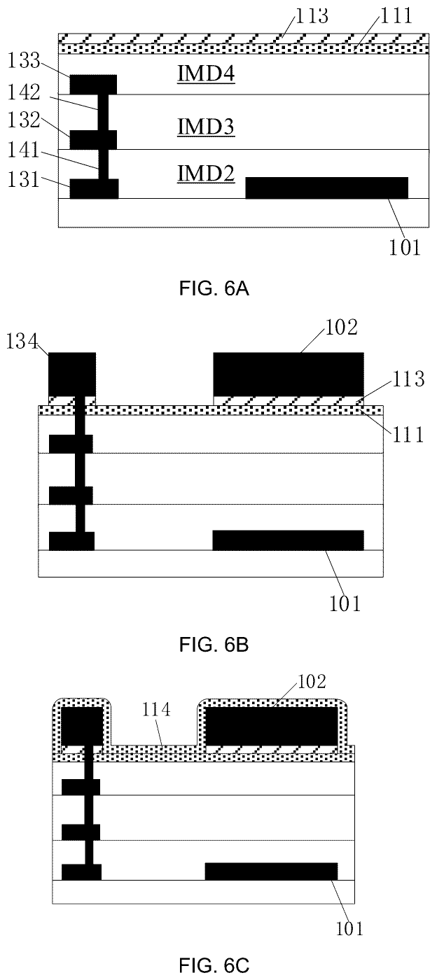

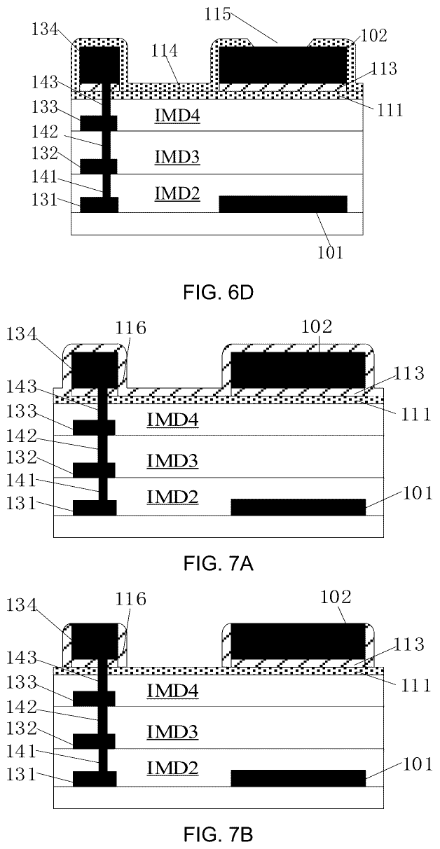

Specifically, as shown in FIG. 6A, a first electrode portion 101 is first formed, then the interlayer dielectric layers (IMD2, IMD3, IMD4) are formed above the first electrode portion 101, and then the first voltage-resistant dielectric layer is formed above the interlayer dielectric layers.

As an example, the high-voltage capacitor comprises a second interlayer dielectric layer IMD2, a third interlayer dielectric layer IMD3, and a fourth interlayer dielectric layer IMD4, the first electrode portion 101 is formed on a first interlayer dielectric layer, and the interlayer dielectric layers IMD2, IMD3, IMD4 are sequentially applied over the first electrode portion 101. The second interlayer dielectric layer IMD2 is formed on exposed portion of first interlayer dielectric layer and first electrode portion 101, and the second interlayer dielectric layer IMD2 may cover upper surface and side surfaces of first electrode portion 101. The process used is an industry standard method for forming interlayer dielectrics.

Further, as an example, the forming of the first voltage-resistant dielectric layer includes forming a lower voltage-resistant dielectric layer 111 on the interlayer dielectric layers; forming an upper voltage-resistant dielectric layer 113 on the lower voltage-resistant dielectric layer. The lower voltage-resistant dielectric layer 111 and the upper voltage-resistant dielectric layer 113 are formed using deposition processes, such as physical vapor deposition (PVD), chemical vapor deposition (CVD), and atomic layer deposition (ALD), among others.

The upper voltage-resistant dielectric layer 113 is made of one of SiON and SiN, and the lower voltage-resistant dielectric layer 111 is made of the other of SiON and SiN. The SiN dielectric layer has a thickness ranging from 0.5 μm to 2 μm, and the SiON dielectric layer has a thickness ranging from 0.5 μm to 1 μm.

In other embodiments, as shown in FIG. 2, the method for forming the first voltage-resistant dielectric layer includes forming a one-layer dielectric structure 211 on the interlayer dielectric layers. The one-layer dielectric structure 211 is made of SiN or SiON.

It's important to note that the high-voltage capacitor is typically integrated into a semiconductor die. This die includes a semiconductor substrate that includes active devices, such as metal-oxide-semiconductor transistors. The semiconductor substrate includes both a high-voltage capacitor region and an active region. The metal layers (131, 132, 133) and conductive via holes (141, 142) are formed above the active region, all of which are configured to lead out electrodes of the active devices. The conductive via holes are electrically connected to adjacent metal layers. The method further includes forming a metal layer on a previous interlayer dielectric layer before stacking a new interlayer dielectric layer on top, and then forming a conductive via hole in the new interlayer dielectric layer. As an example, the metal layer 131 and the first electrode portion 101 are located in the same layer and are formed synchronously.

In other embodiments, the method further includes forming a third voltage-resistant dielectric layer 321 between every two adjacent interlayer dielectric layers. As shown in FIG. 3, the third voltage-resistant dielectric layer 321 is located below a corresponding metal layer.

In addition, the method further comprises forming a via hole in the first voltage-resistant dielectric layer and the topmost interlayer dielectric layer (i.e., the fourth interlayer dielectric layer IMD4), and depositing conductive materials in the via hole to achieve electrical connection.

As shown in FIG. 6B, the second electrode portion 102 is formed on the first voltage-resistant dielectric layer. Specifically, a metal layer is first deposited on the first voltage-resistant dielectric layer, to cover the upper surface of the first voltage-resistant dielectric layer; then the metal layer and the upper voltage-resistant dielectric layer are etched (if the first voltage-resistant dielectric layer has a one-layer dielectric structure, only the metal layer is etched), and the etching is stopped at the upper surface of the lower voltage-resistant dielectric layer. It should be noted that the portion where the upper voltage-resistant dielectric layer needs to be etched can be completely removed by controlling over-etching.

The etching of the metal layer and the upper voltage-resistant dielectric layer includes: forming a patterned photoresist layer on the metal layer to cover part of the metal layer corresponding to the first electrode portion in the vertical direction, etching the metal layer and the upper voltage-resistant dielectric layer by using the photoresist layer as a mask, to form the second electrode portion 102.

Further, the photoresist layer further covers a portion of the metal layer 134 corresponding to the interlayer metal layers (131, 132, 133), and after the etching process, this portion of the metal layer 134 is reserved as an interlayer metal layer.

As shown in FIG. 6C, the second voltage-resistant dielectric layer is formed on the second electrode portion 102 and the first voltage-resistant dielectric layer, surrounding the side surface and the upper surface of the second electrode portion.

As an example, the second voltage-resistant dielectric layer 114 is deposited on the second electrode portion 102 and the first voltage-resistant dielectric layer, and covers an exposed portion of the upper surface of the lower voltage-resistant dielectric layer 111, the upper and side surfaces of the second electrode portion 102 (as well as the metal layer 134), and the side surface of the upper voltage-resistant dielectric layer 113.

As shown in FIG. 6D, the method further comprises etching the second voltage-resistant dielectric layer on the upper surface of the second electrode portion 102 to form an opening 115, exposing part of the upper surface of the second electrode portion. Further, a welding structure is formed on the exposed part of the upper surface of the second electrode portion, allowing the second electrode portion to be electrically connected to an external circuit.

In other embodiments, before forming the second voltage-resistant dielectric layer covering the side surface and the upper surface of the second electrode portion, the method further comprises: forming a fourth voltage-resistant dielectric layer on the first voltage-resistant dielectric layer to cover the side surface of the second electrode portion. The second voltage-resistant dielectric layer is located on the lower voltage-resistant dielectric layer and the second electrode portion, and covers the exposed portion of the upper surface of the lower voltage-resistant dielectric layer, the upper surface of the second electrode portion, and the side surface of the fourth voltage-resistant dielectric layer, as shown in FIG. 4.

The first few steps of the method in these other embodiments are the same as those of FIGS. 6A and 6B in the foregoing embodiments.

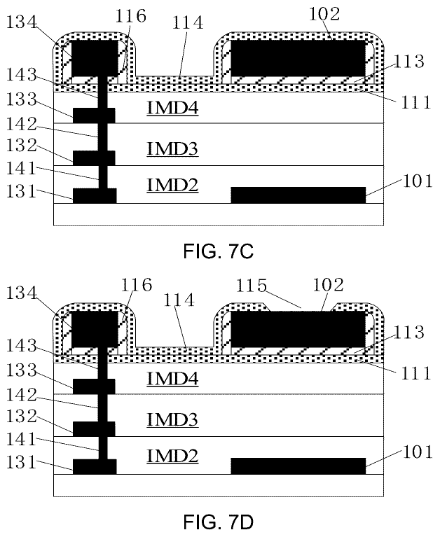

Specifically, as shown in FIG. 7A, the fourth voltage-resistant dielectric layer is formed on the second electrode portion 102 and the first voltage-resistant dielectric layer, surrounding the side surface and the upper surface of the second electrode portion.

As an example, the fourth voltage-resistant dielectric layer 116 is deposited on the second electrode portion 102 and the first voltage-resistant dielectric layer, and covers the exposed portion of the upper surface of the lower voltage-resistant dielectric layer 111, the upper and side surfaces of the second electrode portion 102 (as well as the metal layer 134), and the side surface of the upper voltage-resistant dielectric layer 113. Materials of the fourth voltage-resistant dielectric layer and the upper voltage-resistant dielectric layer are the same.

Specifically, as shown in FIG. 7B, the portion where the fourth voltage-resistant dielectric layer 116 needs to be etched may be completely removed by controlled over-etching, and as an example, the fourth voltage-resistant dielectric layer 116 located on the upper surface of the lower voltage-resistant dielectric layer 111 and the upper surface of the second electrode portion is removed by etching, such that the remaining fourth voltage-resistant dielectric layer 116 covers the side surface of the second electrode portion and the side surface of the upper voltage-resistant dielectric layer.

As shown in FIG. 7C, the second voltage-resistant dielectric layer is formed on the second electrode portion 102 and the first voltage-resistant dielectric layer, surrounding the side surface and the upper surface of the second electrode portion.

As an example, the second voltage-resistant dielectric layer 114 is deposited on the second electrode portion 102 and the lower voltage-resistant dielectric layer, and covers the exposed portion of the upper surface of the lower voltage-resistant dielectric layer 111, the upper surface of the second electrode portion 102 (as well as the metal layer 134), and the side surface of the fourth voltage-resistant dielectric layer 116.

As shown in FIG. 7D, the method further includes etching the second voltage-resistant dielectric layer on the upper surface of the second electrode portion 102 to form an opening 115, exposing part of the upper surface of the second electrode portion 102. Further, a welding structure is formed on the exposed part of the upper surface of the second electrode portion, allowing the second electrode portion to be electrically connected to an external circuit.

It should be understood that the above-mentioned embodiments are only preferred embodiments of the present disclosure and are not intended to restrict the present disclosure. Any modification, equivalent replacement, improvement, etc. made to the present disclosure within the spirit and principle of the present disclosure should be included in the scope of the present disclosure.

1. A method for manufacturing a high-voltage capacitor, comprising:
forming a first electrode portion of the high-voltage capacitor;
stacking one or more interlayer dielectric layers on the first electrode portion;
forming a first voltage-resistant dielectric layer on an upper surface of a topmost interlayer dielectric layer among the interlayer dielectric layers;
forming a second electrode portion of the high-voltage capacitor on the first voltage-resistant dielectric layer, wherein projections of the second electrode portion and the first electrode portion overlap along a vertical direction; and
forming a second voltage-resistant dielectric layer on the second electrode portion and exposed portion of an upper surface of first voltage-resistant dielectric layer,
wherein a dielectric constant of the first voltage-resistant dielectric layer and a dielectric constant of the second voltage-resistant dielectric layer are both greater than a dielectric constant of the interlayer dielectric layers.

2. The method according to claim 1, wherein the forming of the first voltage-resistant dielectric layer comprises forming one layer of voltage-resistant dielectric structure covering the upper surface of the topmost interlayer dielectric layer, wherein materials of the first voltage-resistant dielectric layer and the second voltage-resistant dielectric layer are the same.

3. The method according to claim 1, wherein the forming of the first voltage-resistant dielectric layer comprises:
forming a lower voltage-resistant dielectric layer covering the upper surface of the topmost interlayer dielectric layer;
forming an upper voltage-resistant dielectric layer on the lower voltage-resistant dielectric layer; and
etching the upper voltage-resistant dielectric layer after the second electrode portion is formed on the upper voltage-resistant dielectric layer, to obtain an etched upper voltage-resistant dielectric layer located only below a lower surface of the second electrode portion.

4. The method according to claim 3, wherein the second voltage-resistant dielectric layer is located on the lower voltage-resistant dielectric layer and the second electrode portion, and covers an exposed portion of an upper surface of the lower voltage-resistant dielectric layer, the side surface and the upper surface of the second electrode portion, and a side surface of the upper voltage-resistant dielectric layer.

5. The method according to claim 3, wherein before forming the second voltage-resistant dielectric layer covering the side surface and the upper surface of the second electrode portion, the method further comprises:
forming a fourth voltage-resistant dielectric layer on the first voltage-resistant dielectric layer to cover the side surface of the second electrode portion.

6. The method according to claim 5, wherein the second voltage-resistant dielectric layer is located on the lower voltage-resistant dielectric layer and the second electrode portion to cover an exposed portion of an upper surface of the lower voltage-resistant dielectric layer, the upper surface of the second electrode portion, and a side surface of the fourth voltage-resistant dielectric layer.

7. The method according to claim 3, wherein the upper voltage-resistant dielectric layer is made of one of SiON and SiN, and the lower voltage-resistant dielectric layer is made of the other of SiON and SiN.

8. The method according to claim 1, wherein forming a third voltage-resistant dielectric layer located between every two adjacent interlayer dielectric layers.

9. A high-voltage capacitor, comprising:
a first electrode portion;
one or more interlayer dielectric layers, stacked on the first electrode portion;
a first voltage-resistant dielectric layer, formed on an upper surface of a topmost interlayer dielectric layer among the interlayer dielectric layers;
a second electrode portion, formed on the first voltage-resistant dielectric layer, wherein projections of the second electrode portion and the first electrode portion overlap along a vertical direction; and
a second voltage-resistant dielectric layer, formed on the second electrode portion and exposed portion of an upper surface of first voltage-resistant dielectric layer to at least cover part of an upper surface of the second electrode portion,
wherein a dielectric constant of each of the first voltage-resistant dielectric layer and a dielectric constant of the second voltage-resistant dielectric layer are both greater than a dielectric constant of the interlayer dielectric layers.

10. The high-voltage capacitor according to claim 9, wherein materials of the first voltage-resistant dielectric layer and the second voltage-resistant dielectric layer are the same.

11. The high-voltage capacitor according to claim 9, wherein the first voltage-resistant dielectric layer comprises a lower voltage-resistant dielectric layer and an upper voltage-resistant dielectric layer, and materials of the second voltage-resistant dielectric layer and the lower voltage-resistant dielectric layer are the same, wherein the lower voltage-resistant dielectric layer is away from a lower surface of the second electrode portion compared to the upper voltage-resistant dielectric layer.

12. The high-voltage capacitor according to claim 11, further comprising:
a fourth voltage-resistant dielectric layer, formed on the first voltage-resistant dielectric layer and configured to cover the side surface of the second electrode portion.

13. The high-voltage capacitor according to claim 12, wherein
the second voltage-resistant dielectric layer is configured to locate on the lower voltage-resistant dielectric layer and the second electrode portion, and cover an exposed portion of an upper surface of the lower voltage-resistant dielectric layer, the upper surface of the second electrode portion, and a side surface of the fourth voltage-resistant dielectric layer;
materials of the fourth voltage-resistant dielectric layer and the upper voltage-resistant dielectric layer are the same.

14. The high-voltage capacitor according to claim 10, wherein the first voltage-resistant dielectric layer and the second voltage-resistant dielectric layer are made of SiON or SiN.

15. The high-voltage capacitor according to claim 11, wherein the lower voltage-resistant dielectric layer is made of one of SiON and SiN, and the upper voltage-resistant dielectric layer is made of the other of SiON and SiN.

16. The high-voltage capacitor according to claim 11, wherein the lower voltage-resistant dielectric layer is configured to cover the entire upper surface of the topmost interlayer dielectric layer, and the upper voltage-resistant dielectric layer is located only below the lower surface of the second electrode portion.

17. The high-voltage capacitor according to claim 9, wherein the interlayer dielectric layers and the first voltage-resistant dielectric layer are located between the first electrode portion and the second electrode portion, and have a total thickness greater than or equal to 5 μm and less than or equal to 25 μm.

18. The high-voltage capacitor according to claim 9, wherein a thickness of the first voltage-resistant dielectric layer is greater than or equal to 0.5 μm and less than or equal to 3 μm.

19. The high-voltage capacitor according to claim 9, wherein a third voltage-resistant dielectric layer is located between every two adjacent interlayer dielectric layers.

20. An integrated device, comprising:
a substrate, comprising a first region and a second region, wherein the second region is provided with a semiconductor device;
the high-voltage capacitor according to claim 9, located above the first region; and
metal layers and conductive via holes, located in the interlayer dielectric layers and above the second region,
wherein the metal layers and the conductive via holes are configured to lead out electrodes of the semiconductor device, the first electrode portion is formed synchronously with a metal layer located in a same interlayer dielectric layer as the first electrode portion, and the second electrode portion is formed synchronously with a metal layer located in a same interlayer dielectric layer as the second electrode portion.
